(19) United States
(12) Patent Application Publication
(10) Pub. No.: US 2026/0173770 A1
(43) Pub. Date: Jun. 18, 2026

(54) SELECTABLE TUNNEL JUNCTIONS BASED ON IN-LINE MEASURED RESISTANCE

(71) Applicant: International Business Machines Corporation, Armonk, NY (US)

(72) Inventors: Jeffrey W. Sleight, Ridgefield, CT (US); Isaac Lauer, Chappaqua, NY (US); Karthik Balakrishnan, Scarsdale, NY (US); David James Frank, Yorktown Heights, NY (US)

(21) Appl. No.: 18/981,459

(22) Filed: Dec. 14, 2024

(51) Int. Cl. H10N 60/10; G01R 33/035; H10N 60/80

(52) U.S. Cl. CPC H10N 60/11; G01R 33/0354; H10N 60/80

(57) ABSTRACT

A qubit structure includes a substrate; a first planar metal portion residing on the substrate; a second planar metal portion residing on the substrate; a plurality of candidate tunnel junctions, a first end of each candidate tunnel junction coupled to the first planar metal portion; and a plurality of pads, each pad coupled to a second end of each candidate tunnel junction.

### BACKGROUND

The present invention relates generally to the electrical, electronic and computer arts and, more particularly, to quantum devices.

Tunnel junctions are a central component of qubits. Generally, tunnel junctions are a structure including a metal/insulator/metal configuration where, for the structure of a qubit, the metals are superconductive at cryogenic temperatures. In qubit device structures, the control of the tunnel junction resistance at room temperature is a significant parameter in determining the qubit operational frequency, f_{q}, at cryogenic operating temperatures when the tunnel junction (also referred to as a junction herein) is performing as part of a quantum device. Control of the junction size and the junction resistance through current best-known junction formation processes is not sufficient for the tolerances required for a quantum processor.

### BRIEF SUMMARY

Principles of the invention provide systems and techniques for selectable tunnel junctions based on in-line measured resistance. In one aspect, an exemplary method includes the operations of measuring a resistance between a first planar metal portion and each of a plurality of pads, the first planar metal portion being coupled to one end of each of a plurality of tunnel junctions and each of the plurality of pads being coupled to a corresponding one of the plurality of tunnel junctions; selecting an optimal tunnel junction of the plurality of tunnel junctions, the optimal tunnel junction having a measured resistance closest to a target resistance; and coupling the pad corresponding to the selected tunnel junction to the second planar metal portion 228 with a connector.

In one aspect, a qubit structure comprises a substrate; a first planar metal portion residing on the substrate; a second planar metal portion residing on the substrate; a plurality of candidate tunnel junctions, a first end of each candidate tunnel junction being coupled to the first planar metal portion; and a plurality of pads, each pad being coupled to a second end of each candidate tunnel junction.

In one aspect, a cryogenic system comprises a cryostat configured to cool to cryogenic temperatures; a qubit structure residing in the cryostat, the qubit structure further comprising a substrate; a first planar metal portion residing on the substrate; a second planar metal portion residing on the substrate; a plurality of candidate tunnel junctions, a first end of each candidate tunnel junction being coupled to the first planar metal portion; and a plurality of pads, each pad being coupled to a second end of each candidate tunnel junction.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
accurate control of the resistance of a tunnel junction of a qubit device at room temperature;
accurate control of the operational frequency, f_{q}, of a qubit device operating at cryogenic temperatures when the tunnel junction is performing as a component of a quantum device; and
accurate control of the maximum or minimum operational frequency, f_{q}, of a qubit
implemented as a superconducting quantum interference device (SQUID) where the frequency of the qubit is controllable with the magnetic field of the Squid loop.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A illustrates metal layers of a qubit residing on a substrate, in accordance with example embodiments;

FIG. 1B illustrates a configuration for measuring the resistance of each tunnel junction, in accordance with example embodiments;

FIG. 1C illustrates the metal layers of a qubit after incorporating a selected tunnel junction of the plurality of tunnel junctions into the qubit, in accordance with example embodiments;

FIG. 1D illustrates the metal layers of a qubit after incorporating two selected tunnel junctions of the plurality of tunnel junctions into the qubit to create a superconducting quantum interference device (SQUID) loop configuration, in accordance with example embodiments;

FIG. 2 is a flow diagram of a design process used in semiconductor design, manufacture, and/or test;

FIG. 3 depicts a computing environment according to an embodiment of the present invention; and

FIG. 4 shows an exemplary context in which selectable tunnel junctions in accordance with aspects of the invention could be employed, including superconducting metal line(s) between first and second quantum computing elements, within a cryostat.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

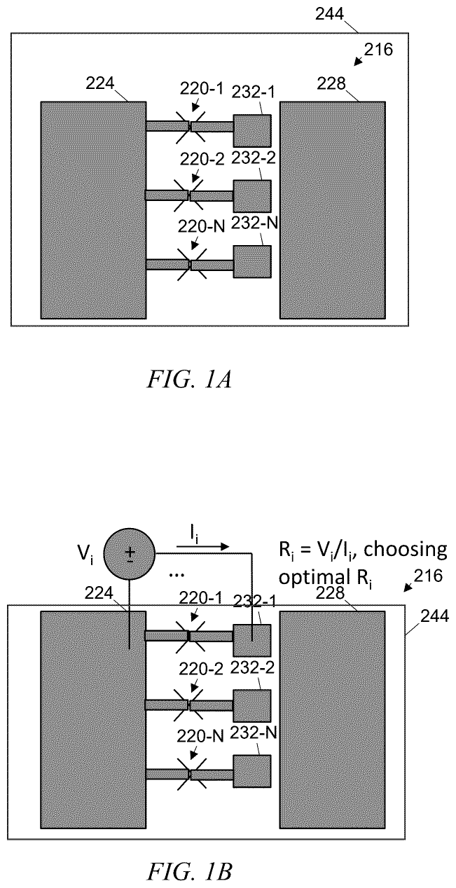

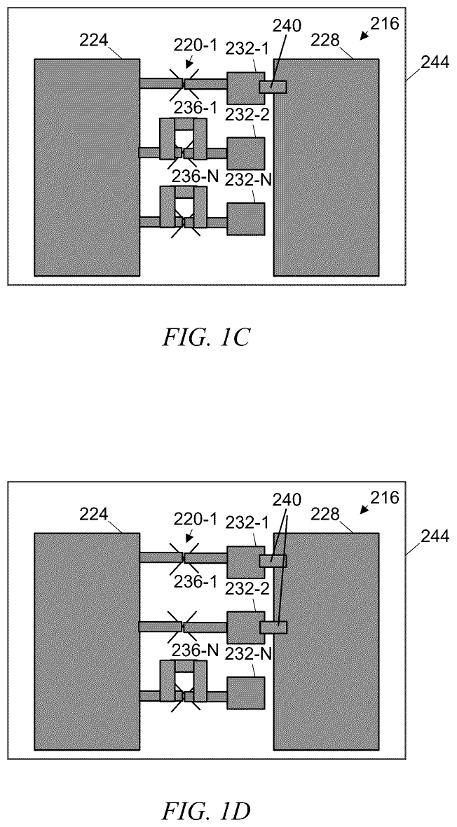

In qubit device structures, the control of the tunnel junction resistance at room temperature is a critical parameter in determining the qubit operational frequency, f_{q}, at cryogenic operating temperatures when the tunnel junction is performing as a component of a quantum device. Conventionally, the size of the junction and the area of the junction correlate with the resistance of the tunnel junction: a larger junction area correlates with a smaller resistance. Size, however, is not a well-controlled fabrication parameter; the resulting area and corresponding resistance will typically not meet the tolerances of a quantum processor. FIG. 1A illustrates metal layers of a qubit 216 residing on a substrate 244, in accordance

with example embodiments. In example embodiments, rather than have one tunnel junction 220-1 connecting the planar metal 224, 228 of the qubit 216, the planar metal 224 (also referred to as planar metal portion herein) of the qubit 216 on one side of the qubit 216 is connected to multiple tunnel junctions 220-1, 220-2, . . . , 220-N where N is, for example, equal to three. The other side of each tunnel junction 220-1, 220-2, . . . , 220-N is connected to an electrically-probeable pad 232-1, 232-2, . . . , 232-N.

After fabrication, the resistance of each of the tunnel junctions 220-1, 220-2, . . . , 220-N is measured (using, for example, a probe card). FIG. 1B illustrates an exemplary configuration for measuring the resistance of each tunnel junction 220-1, 220-2, . . . , 220-N. In example embodiments, a first probe is applied to the planar metal 224 and a second probe is applied to one of the electrically-probeable pads 232-1, 232-2, . . . , 232-N to measure the resistance of the tested tunnel junction 220-1, 220-2, . . . , 220-N. In example embodiments, a plurality of pads 232-1, 232-2, . . . , 232-N are used to measure a plurality of tunnel junctions 220-1, 220-2, . . . , 220-N simultaneously.

FIG. 1C illustrates the metal layers of a qubit 216 after incorporating a selected tunnel junction 220-1, 220-2, . . . , 220-N of the plurality of tunnel junctions 220-1, 220-2, . . . , 220-N into the qubit 216, in accordance with example embodiments. A certain one of the tunnel junctions 220-1, 220-2, . . . , 220-N having the resistance that is closest to the target resistance is selected and the corresponding electrically-probeable pad 232-1, 232-2, . . . , 232-N is connected to the unconnected planar metal 228 of the qubit 216 via connector 240. The remaining tunnel junctions(i.e., other than the selected certain one) of the tunnel junctions 220-1, 220-2, . . . , 220-N are modified to ensure that they do not contribute to the qubit circuit. In example embodiments, the remaining tunnel junctions 220-1, 220-2, . . . , 220-N are short-circuited with connectors 236-1, 236-N to ensure that they do not contribute to the qubit circuit. In example embodiments, the remaining tunnel junctions 220-1, 220-2, . . . , 220-N are subjected to an overcurrent to blow them out to ensure that they do not contribute to the qubit circuit. The overcurrent may be applied, for example, during the resistance measurement phase.

Example embodiments are based on creating Transmon qubits, also referred to as fixed frequency Transmon qubits herein. FIG. 1D illustrates the metal layers of a qubit after incorporating two selected tunnel junctions of the plurality of tunnel junctions into the qubit to create a superconducting quantum interference device (SQUID) loop configuration, in accordance with example embodiments. By incorporating two junctions 220-1, 220-2, . . . , 220-N in the qubit 216, a superconducting quantum interference device (SQUID) loop is formed where the frequency of the qubit 216 is controllable with the magnetic field of the SQUID loop. For the described tunable frequency qubits, the frequency range is determined by the resistance of the selected tunnel junctions 220-1, 220-2, . . . , 220-N. In example embodiments, two neighboring junctions 220-1, 220-2, . . . , 220-N of the candidate tunnel junctions 220-1, 220-2, . . . , 220-N are kept to form the SQUID loop. In other example embodiments, however, the candidate tunnel junctions 220-1, 220-2, . . . , 220-N that are kept to form the Squid loop are not necessarily neighboring candidate tunnel junctions 220-1, 220-2, . . . , 220-N.

In example embodiments, two or more pairs of tunnel junctions 220-1, 220-2, . . . , 220-N are kept (e.g., k junctions kept and N-k junctions removed).

In example embodiments, lithography is used to form the connectors 236-1, . . . , 236-N, the connector(s) 240 between the electrically-probeable pad 232-1, 232-2, . . . , 232-N and the unconnected planar metal 228 of the qubit 216, or both. For example, using electron beam lithography, a shape for the connector 204 is selected from a library and a file for an electron beam lithography tool (to pattern the photoresist) is generated. Similarly, direct write optical lithography using a laser can be used to open windows for the connector(s) 240, the connectors 236-1, 236-N or both.

Ion beam matching or a sputter cleaning technique can be used to clean off the top of the metal surfaces, such as the electrically-probeable pads 232-1, 232-2, . . . , 232-N and the planar metal 228. An aluminum film can then be evaporated on the exposed metal parts to form the connector(s) 240, the connectors 236-1, . . . , 236-N, or both, and a solvent rinse can be applied to rinse off the photoresist and wash away the metal outside of the connector(s) 240, the connectors 236-1, . . . , 236-N, or both.

It is noted that, conventionally, laser annealing of stochastically impaired qubits (LASIQ) techniques provide a laser anneal that can be used to tune the tunnel junctions 220-1, 220-2, . . . , 220-N; however, the yields attained with the LASIQ technique are generally unsatisfactory (in many, but not necessarily all, cases). Moreover, tunnel junctions 220-1, 220-2, . . . , 220-N created using LASIQ are known to drift over time. For example, the junction resistance of the qubit may drift over time. In example embodiments, LASIQ is used in combination with the techniques described above to create qubits having tunnel junctions 220-1, 220-2, . . . , 220-N that meet the specifications of quantum processors. For example, the tunnel junctions 220-1, 220-2, . . . , 220-N (or the selected tunnel junction(s) 220-1, 220-2, . . . , 220-N) can be subjected to LASIQ to tune the junction resistance.

Given the discussion thus far, it will be appreciated that, in general terms, an exemplary method, according to an aspect of the invention, includes the operations of measuring a resistance between a first planar metal portion 224 and each of a plurality of pads 232-1, 232-2, . . . , 232-N, the first planar metal portion 224 being coupled to one end of each of a plurality of tunnel junctions 220-1, 220-2, . . . , 220-N and each of the plurality of pads 232-1, 232-2, . . . , 232-N being coupled to a corresponding one of the plurality of tunnel junctions 220-1, 220-2, . . . , 220-N; selecting an optimal tunnel junction 220-1, 220-2, . . . , 220-N of the plurality of tunnel junctions 220-1, 220-2, . . . , 220-N, the optimal tunnel junction 220-1, 220-2, . . . , 220-N having a measured resistance closest to a target resistance; and coupling the pad 232-1, 232-2, . . . , 232-N corresponding to the selected tunnel junction 220-1, 220-2, . . . , 220-N to the second planar metal portion 228 with a connector 240.

In example embodiments, one or more metal connections 236-1, . . . , 236-N are fabricated, each metal connection 236-1, . . . , 236-N configured to short circuit a corresponding non-selected tunnel junction 220-1, 220-2, . . . , 220-N.

In example embodiments, non-selected candidate tunnel junctions 220-1, 220-2, . . . , 220-N are rendered incapable of impacting an operation of a corresponding qubit structure.

In example embodiments, the rendering the non-selected tunnel junctions 220-1, 220-2, . . . , 220-N to be incapable of impacting the operation of the qubit structure is performed during a measurement phase of a fabrication process.

In example embodiments, the rendering the non-selected tunnel junctions 220-1, 220-2, . . . , 220-N to be incapable of impacting the operation of the qubit structure further comprises applying a high current, a high voltage or both to the non-selected tunnel junctions 220-1, 220-2, . . . , 220-N.

In example embodiments, the measuring of the resistances between the first planar metal portion 224 and at least a plurality of the pads 232-1, 232-2, . . . , 232-N is performed in parallel.

In example embodiments, a laser annealing of stochastically impaired qubits (LASIQ) process is performed on at least the selected tunnel junction 220-1, 220-2, . . . , 220-N.

In example embodiments, a second tunnel junction 220-1, 220-2, . . . , 220-N of the plurality of tunnel junctions 220-1, 220-2, . . . , 220-N is selected, the second tunnel junction 220-1, 220-2, . . . , 220-N being a neighboring tunnel junction 220-1, 220-2, . . . , 220-N of the optimal tunnel junction 220-1, 220-2, . . . , 220-N and having a measured resistance closest to the target resistance of any of the neighboring tunnel junctions 220-1, 220-2, . . . , 220-N; and the pad 232-1, 232-2, . . . , 232-N corresponding to the selected neighboring tunnel junction 220-1, 220-2, . . . , 220-N is coupled to the second planar metal portion 228 with a second connector 240 to form a superconducting quantum interference device (SQUID) when operated at cryogenic temperatures.

In example embodiments, the superconducting quantum interference device (SQUID) is operated at cryogenic temperatures in a cryostat.

In example embodiments, the measured resistances are compared to identify the optimal tunnel junction 220-1, 220-2, . . . , 220-N.

In one aspect, a qubit structure comprises a substrate 244; a first planar metal portion 224 residing on the substrate 244; a second planar metal portion 228 residing on the substrate 244; a plurality of candidate tunnel junctions 220-1, 220-2, . . . , 220-N, a first end of each candidate tunnel junction 220-1, 220-2, . . . , 220-N being coupled to the first planar metal portion 224; and a plurality of pads 232-1, 232-2, . . . , 232-N, each pad 232-1, 232-2, . . . , 232-N being coupled to a second end of each candidate tunnel junction 220-1, 220-2, . . . , 220-N.

In example embodiments, the qubit structure includes a metal connector 240 coupling the second planar metal portion 228 and a selected one of the candidate tunnel junctions 220-1, 220-2, . . . , 220-N.

In example embodiments, the metal connector 240 is implemented with a metal or metal alloy that becomes superconducting at cryogenic temperatures.

In example embodiments, the qubit structure includes a plurality of metal connectors 240, each metal connector 240 coupling the second planar metal portion 228 and a selected plurality of the candidate tunnel junctions 220-1, 220-2, . . . , 220-N.

In example embodiments, the first planar metal portion 224 and the second planar metal portion 228 are implemented with a metal or metal alloy that becomes superconducting at cryogenic temperatures.

In example embodiments, the qubit structure includes a metal connection 236-1, 236-N configured to short circuit one or more of the candidate tunnel junctions 220-1, 220-2, . . . , 220-N.

In example embodiments, the qubit structure includes a second metal connector 240 coupling the second planar metal portion 228 and a selected one of the candidate tunnel junctions 220-1, 220-2, . . . , 220-N.

In example embodiments, the second metal connector 240 is implemented with a metal or metal alloy that becomes superconducting at cryogenic temperatures.

In one aspect, a cryogenic system comprises a cryostat configured to cool to cryogenic temperatures; a qubit structure residing in the cryostat, the qubit structure further comprising a substrate 244; a first planar metal portion 224 residing on the substrate 244; a second planar metal portion 228 residing on the substrate 244; a plurality of candidate tunnel junctions 220-1, 220-2, . . . , 220-N, a first end of each candidate tunnel junction 220-1, 220-2, . . . , 220-N being coupled to the first planar metal portion 224; and a plurality of pads 232-1, 232-2, . . . , 232-N, each pad 232-1, 232-2, . . . , 232-N being coupled to a second end of each candidate tunnel junction 220-1, 220-2, . . . , 220-N.

In example embodiments, the qubit structure further comprises a second metal connector 240 coupling the second planar metal portion 228 and a selected one of the candidate tunnel junctions 220-1, 220-2, . . . , 220-N.

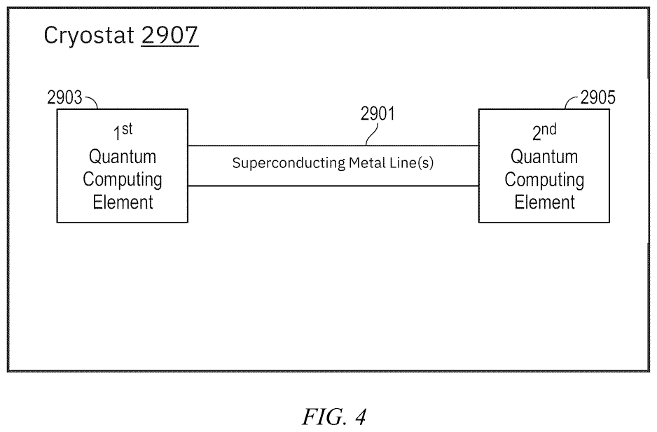

Referring now to FIG. 4, one or more embodiments include one or more superconducting metal lines (also referred to as traces) 2901 that interconnect at least first and second quantum computing elements 2903, 2905. In one or more embodiments, a quantum computing structure includes the first quantum computing element 2903 coupled to the first end of line(s) 2901 and the second quantum computing element 2905 coupled to the second end of line(s) 2901. The coupling can be direct or indirect; i.e., there can be other elements between the first end of line(s) 2901 and the first quantum computing element 2903 and/or there can be other elements between the second end of line(s) 2901 and the second quantum computing element 2905. Exemplary selectable tunnel junctions disclosed herein can, for example, be part of the quantum computing elements 2903 and/or 2905, or can be connected to the superconducting metal line(s) 2901.

It will be appreciated that there are many possible use cases and many different types of quantum computing elements possible. For example, there can be a physical manifestation of a qubit at each end of line(s) 2901; a transmission line at each end; a qubit at one end and a readout port at the other end; and so on (e.g., the qubit could be “two steps down the line” from the end of the line(s)). In one or more embodiments, the inventive structure(s) is/are part of an overall qubit system.

In some instances, line(s) 2901 carry signals for a quantum processing unit; say to a qubit, to a coupler, in between different resonators, for signal delivery, or the like. In some instances, one end is coupled to a quantum computing signal source, and the other end is coupled to a quantum computing signal sink - in some cases, a sink could sometimes be a source and vice versa. Coupling can be direct or indirect. For example, a signal source can be off chip, at room temperature outside the cryostat 2907, with intervening connections to the line(s) 2901. The elements can include ports, signal input/output, and the like.

A quantum computing processor is typically passive and signals are applied to it to manipulate it—it does not generate any signals of its own. Quantum computing elements 2903, 2905 can generally be passive or active. Line(s) 2901 can also provide a connection between a first port and a second port. Elements 2903 and 2905 could also include parametric amplifiers, for example.

Accordingly, in some instances, at least one of the first and second quantum computing elements 2903, 2905 includes a physical manifestation of a qubit; in some instances, at least one of the first and second quantum computing elements includes a readout port; and in some instances, at least one of the first and second quantum computing elements includes a transmission line.

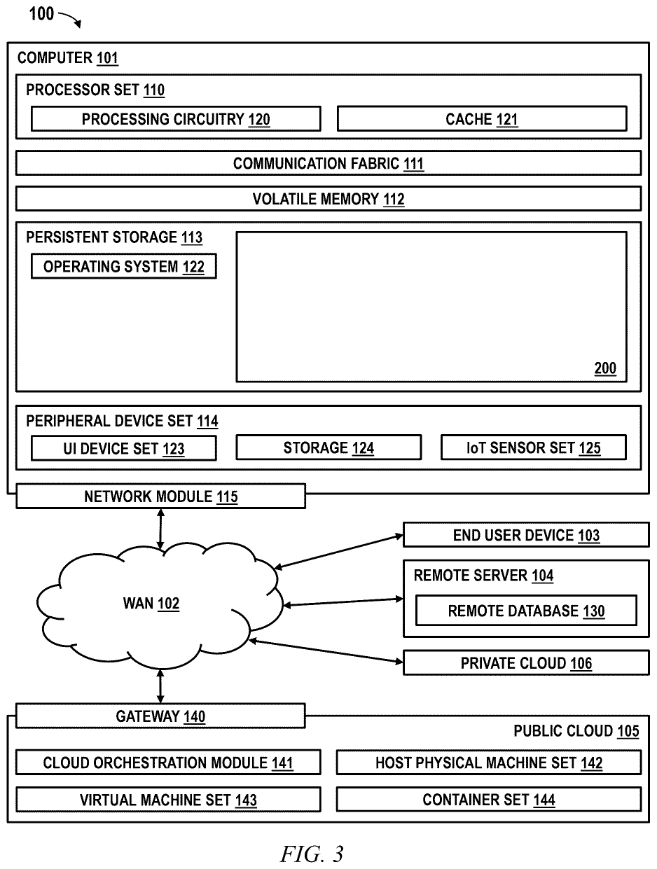

A dilution refrigerator is a non-limiting example of a suitable cryostat 2907; any suitable refrigeration device capable of producing temperatures less than 10 Kelvin can be employed. refer now to FIG. 3.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

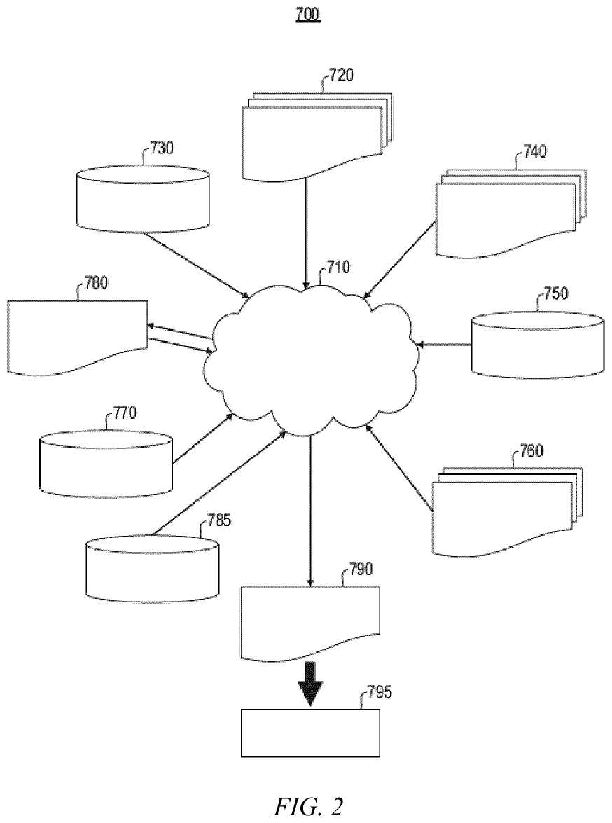

Computing environment 100 contains an example of an environment for the execution of at least some of the computer code involved in performing the inventive methods, such as a system (see block 200) for semiconductor design and/or control of semiconductor fabrication (see FIG. 2, discussed elsewhere herein). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 3. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 2 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 2 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., . lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A qubit structure comprising:
a substrate;
a first planar metal portion residing on the substrate;
a second planar metal portion residing on the substrate;
a plurality of candidate tunnel junctions, a first end of each candidate tunnel junction coupled to the first planar metal portion; and
a plurality of pads, each pad coupled to a second end of each candidate tunnel junction.

2. The qubit structure of claim 1, further comprising a metal connector coupling the second planar metal portion and a selected one of the candidate tunnel junctions.

3. The qubit structure of claim 2, wherein the metal connector is implemented with a metal or metal alloy that becomes superconducting at cryogenic temperatures.

4. The qubit structure of claim 2, further comprising a plurality of metal connectors, each metal connector coupling the second planar metal portion and a selected plurality of the candidate tunnel junctions.

5. The qubit structure of claim 2, wherein the first planar metal portion and the second planar metal portion are implemented with a metal or metal alloy that becomes superconducting at cryogenic temperatures.

6. The qubit structure of claim 2, further comprising a metal connection configured to short circuit one or more of the candidate tunnel junctions.

7. The qubit structure of claim 6, further comprising a second metal connector coupling the second planar metal portion and a selected one of the candidate tunnel junctions.

8. The qubit structure of claim 7, wherein the second metal connector is implemented with a metal or metal alloy that becomes superconducting at cryogenic temperatures.

9. A method comprising:
measuring a resistance between a first planar metal portion and each of a plurality of pads, the first planar metal portion being coupled to one end of each of a plurality of tunnel junctions and each of the plurality of pads being coupled to a corresponding one of the plurality of tunnel junctions;
selecting an optimal tunnel junction of the plurality of tunnel junctions, the optimal tunnel junction having a measured resistance closest to a target resistance; and
coupling the pad corresponding to the selected tunnel junction to the second planar metal portion with a connector.

10. The method of claim 9, further comprising fabricating one or more metal connections, each metal connection configured to short circuit a corresponding non-selected tunnel junction.

11. The method of claim 9, further comprising:
rendering non-selected candidate tunnel junctions incapable of impacting an operation of a corresponding qubit structure.

12. The method of claim 11, wherein the rendering the non-selected tunnel junctions to be incapable of impacting the operation of the qubit structure is performed during a measurement phase of a fabrication process.

13. The method of claim 11, wherein the rendering the non-selected tunnel junctions to be incapable of impacting the operation of the qubit structure further comprises applying a high current, a high voltage or both to the non-selected tunnel junctions.

14. The method of claim 9, wherein the measuring of the resistances between the first planar metal portion and at least a plurality of the pads is performed in parallel.

15. The method of claim 9, further comprising performing laser annealing of stochastically impaired qubits (LASIQ) process on at least the selected tunnel junction.

16. The method of claim 9, further comprising selecting a second tunnel junction of the plurality of tunnel junctions, the second tunnel junction being a neighboring tunnel junction of the optimal tunnel junction and having a measured resistance closest to the target resistance of any of the neighboring tunnel junctions; and
coupling the pad corresponding to the selected neighboring tunnel junction to the second planar metal portion with a second connector to form a superconducting quantum interference device (SQUID) when operated at cryogenic temperatures.

17. The method of claim 16, further comprising operating the superconducting quantum interference device (SQUID) at cryogenic temperatures in a cryostat.

18. The method of claim 9, further comprising comparing the measured resistances to identify the optimal tunnel junction.

19. A cryogenic system comprising:
a cryostat configured to cool to cryogenic temperatures;
a qubit structure residing in the cryostat, the qubit structure further comprising:
a substrate;
a first planar metal portion residing on the substrate;
a second planar metal portion residing on the substrate;
a plurality of candidate tunnel junctions, a first end of each candidate tunnel junction coupled to the first planar metal portion; and
a plurality of pads, each pad coupled to a second end of each candidate tunnel junction.

20. The cryogenic system of claim 19, wherein the qubit structure further comprises a second metal connector coupling the second planar metal portion and a selected one of the candidate tunnel junctions.
